(19) United States
(12) Patent Application Publication
(10) Pub. No.: US 2008/0135863 A1
(43) Pub. Date: Jun. 12, 2008

(54) OPTICAL SEMICONDUCTOR DEVICE AND OPTICAL TRANSMISSION DEVICE

(75) Inventor: Seigo ONOBUCHI, Fukuoka-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 11/925,216

(22) Filed: Oct. 26, 2007

(30) Foreign Application Priority Data
Oct. 27, 2006 (JP) 2006-292846

(51) Int. Cl. H01L 33/00

(52) U.S. Cl. 257/98; 257/E33.067

(57) ABSTRACT

An optical semiconductor device comprising: an internal lead; an optical semiconductor element mounted on the internal lead and electrically connected to the internal lead; a sealing resin for sealing the optical semiconductor element and the internal lead, the sealing resign provided with an attachment hole formed by side surfaces and a bottom surface, the side surfaces each including a convex curved-surface section in an upper portion and a planar-surface section in a lower portion contiguous to the curved-surface section, and the bottom surface being in a lower portion and facing the front surface of a functional region for emitting or receiving light of the optical semiconductor element, and the sealing resin being transparent to outgoing or incoming light; and an external terminal connected to the internal lead and adapted for surface mount.

### CROSS-REFERENCE TO RELATED APPLICATION

This application is based upon and claims the benefit of priority from the prior Japanese Patent Application No. 2006-292846, filed on Oct. 27, 2006, the entire contents of which are incorporated herein by reference.

### BACKGROUND OF THE INVENTION

1. Field of the Invention

The present invention relates to an optical semiconductor device and an optical transmission device.

2. Description of the Related Art

An optical transmission device in which an optical fiber and an optical semiconductor element (optical semiconductor chip) for the connection of the optical fiber are joined together directly has been disclosed (see Japanese Patent Application Laid-open Publication No. Hei 10-242525, for example). More specifically, in this optical transmission device, the optical semiconductor chip (optical semiconductor element) is housed in a case (a package) that is sealed with a plastic mold (a sealing resin). The case is provided with an attachment hole for attaching an optical fiber by insertion. The attachment hole is coaxial with the optical semiconductor chip, and the bottom surface of the attachment hole faces the optical semiconductor chip. With this technique, an optical transmission device that does not require an optical connector can be provided.

However, the disclosed optical transmission device was designed to use an insertion-type external lead connected to the optical semiconductor element. In addition, a conventional type of fiber, such as a plastic optical fiber (POF) or a silica glass fiber, is supposed to be used as an optical fiber. Accordingly, the disclosed optical transmission device has problems that a substrate supporting the insertion-type lead is needed for mounting the optical transmission device since the external lead extends in the emission direction or the incident direction of light, and that a relatively large space for mounting the device is also required on the optical fiber side.

### SUMMARY OF THE INVENTION

According to an aspect of the present invention, there is provided an optical semiconductor device comprising:

an internal lead;

an optical semiconductor element mounted on the internal lead and electrically connected to the internal lead;

a sealing resin for sealing the optical semiconductor element and the internal lead, the sealing resign provided with an attachment hole formed by side surfaces and a bottom surface, the side surfaces each including a convex curved-surface section in an upper portion and a planar-surface section in a lower portion contiguous to the curved-surface section, and the bottom surface being in a lower portion and facing the front surface of a functional region for emitting or receiving light of the optical semiconductor element, and the sealing resin being transparent to outgoing or incoming light; and

an external terminal connected to the internal lead and adapted for surface mount.

According to another aspect of the present invention, there is provided an optical transmission device comprising:

an internal lead;

an optical semiconductor element mounted on the internal lead and electrically connected to the internal lead;

a sealing resin for sealing the optical semiconductor element and the internal lead, the sealing resin being transparent to outgoing or incoming light;

an optical transmission medium having one end face disposed so as to face the front surface of a functional region for emitting or receiving light of the optical semiconductor device, and having a parallel portion and a linear portion fixed in contact with the sealing resin, the parallel portion being contiguous to the one end face and being parallel to the axis perpendicularly passing through the center of the front surface, and the linear portion being contiguous to the parallel portion and forming a certain angle with the parallel portion; and

an external terminal connected to the internal lead and adapted for surface mount.

### BRIEF DESCRIPTION OF THE DRAWINGS

FIG. 1A and FIG. 1B schematically show a configuration of an optical semiconductor device according to a first embodiment of the present invention. FIG. 1A is a plane view, and FIG. 1B is a sectional view taken along the line A-A in FIG. 1A.

FIG. 2 is a sectional view that schematically shows a configuration of an optical transmission device according to the first embodiment of the invention.

FIGS. 3A to 3C schematically show a configuration of an optical transmission device according to a second embodiment of the invention. FIG. 3A is a plane view, FIG. 3B is a side view, and FIG. 3C is a sectional view taken along the line B-B in FIG. 3A.

### DETAILED DESCRIPTION OF THE INVENTION

Descriptions will be given of embodiments of the present invention with reference to the drawings. In the drawings shown below, the same components are denoted by the same reference numerals and symbols.

### First Embodiment

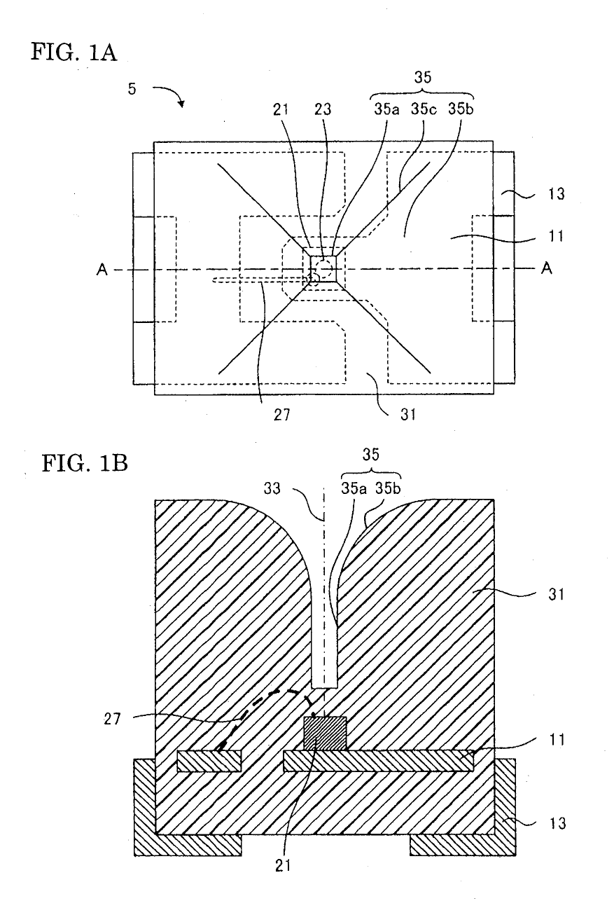

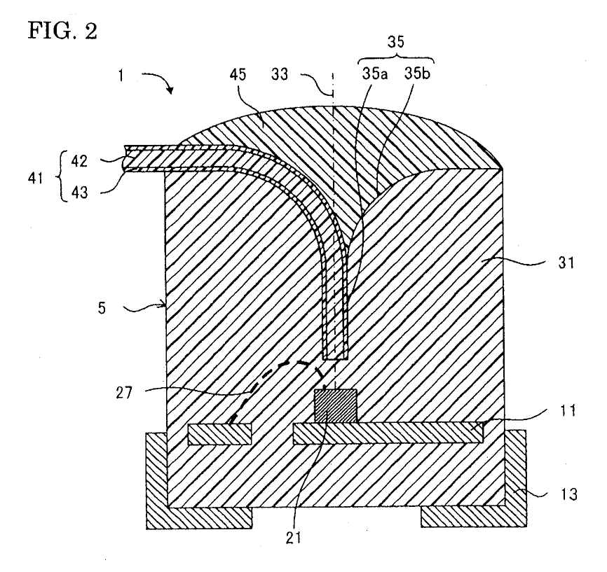

A description will be given of an optical semiconductor device and an optical transmission device according to a first embodiment of the invention with reference to FIGS. 1A and 1B and FIG. 2. FIGS. 1A and 1B schematically show a configuration of the optical semiconductor device. FIG. 1A is a plane view, and FIG. 1B is a sectional view taken along the line A-A in FIG. 1A. FIG. 2 is a sectional view that schematically shows a configuration of the optical transmission device.

As shown in FIGS. 1A and 1B, an optical semiconductor device 5 includes: an optical semiconductor element 21; internal leads 11 provided with, and electrically connected to, the optical semiconductor element 21; a sealing resin 31 for sealing the optical semiconductor element 21 and the internal leads 11, the sealing resign being transparent to outgoing or incoming light; and external terminals 13 connected to the internal leads 11 and adapted for surface mount. The sealing resin 31 is provided with an attachment hole 35 formed of the side surfaces and a bottom surface. Each of the side surfaces is composed of a convex curved-surface section 35b in an upper portion and a planar-surface section 35a in a lower portion contiguous to the curved-surface section 35b. The bottom surface is located in the lower portion, and faces the surface of a functional region 23 for emitting or receiving light of the optical semiconductor element 21.

In a case where the optical semiconductor device 5 is a transmitting device, the optical semiconductor element 21 is a light-emitting element, such as a laser diode (LD) that includes a light-emitting diode (LED) or a vertical cavity surface emitting laser (VCSEL), for example. By contrast, in a case where the optical semiconductor device 5 is a receiving device, the optical semiconductor element 21 is a light-receiving element, such as a photo diode (PD), for example. The light-emitting element emits near-red light or visible light in red color or the like, while the light-receiving element, for example, a silicon PD, has sufficient sensitivity to the light to be received. A bonding pad (not shown) is formed on the light-emitting element, or the light-receiving element, excluding the center on the front surface of the functional region 23 for emitting or receiving light.

The internal leads 11 and the external terminals 13 are a part of a lead frame, which is made of Cu, alloy that contains Cu as the major component, or Fe—Ni alloy (for example, 42 alloy). One of the internal leads 11 and two of the external terminals 13 are formed into desired shapes by means of punching, etching or the like, and make a two-terminal configuration that is capable of supplying a signal (or power) to the optical semiconductor element 21. As shown in FIG. 1A, the optical semiconductor element 21 is fixed to a certain position on the one internal lead 11, the position being in an approximate center of the plane view. The back face of the optical semiconductor element 21 is electrically connected to the one internal lead 11. A periphery of the front face of the optical semiconductor element 21 is connected to the other internal lead 11 through a bonding wire, for example, an Au wire 27. In reality, the Au wire 27 does not appear in the sectional view in FIG. 1B. However, since the Au wire 27 is provided in a vicinity of the cross section, the position of the Au wire 27 is indicated by a dashed line in the sectional view of FIG. 1B, the position corresponding to that of the Au wire 27 in the front view of FIG. 1A.

The external terminals 13 are connected to the internal leads 11. An end portion of each of the external terminals 13 is bent toward the side opposite the surface of the one internal lead 11 on which the optical semiconductor element 21 is mounted, thereby forming an angular C-shape serving as a connecting terminal adapted for surface mount.

The internal leads 11, the optical semiconductor element 21, the Au wire 27 and the like are sealed with the sealing resin 31, which is substantially transparent to light to be used. The sealing resin 31 is, for example, an epoxy resin. The attachment hole 35 is formed in the sealing resin 31, and is used for inserting an optical transmission medium, such as a film optical waveguide or a plastic optical fiber (POF), from the top face of the sealing resin 31.

The lower portion of the attachment hole 35 is located right above the optical semiconductor element 21, and is formed of the rectangular bottom surface that can approximately contain an entire square pole, and the side surfaces comprised of four planar-surface sections 35a. The rectangular bottom surface faces the functional region 23 of the optical semiconductor element 21. An axis 33 that perpendicularly passes through the center of the front surface of the functional region 23 approximately corresponds to the axis that passes through the center of the bottom face of the square pole. The upper portion of the attachment hole 35 is formed so as to have the dimensions that become larger toward the top surface. For example, the upper portion of the attachment hole 35 is formed of the side surfaces comprised of the four curved-surface sections 35b, each of which has a certain curvature similar to that of the side face of a circular cylinder. The four curved-surface sections 35b are each formed to have a convex curved-surface, and intersect with each other at the borderlines 35c. The planar-surface sections 35a are respectively joined smoothly to the curved-surface sections 35b, and the curved-surface sections 35b are also smoothly joined to the top face of the sealing resin 31. The top face of the sealing resin 31 and each of the planar-surface sections 35a are approximately at right angles to each other. The line of intersection of each of the curved-surface sections 35b and a face crossing the axis 33 forms a segment of a circle or an ellipse.

Here, the side surfaces of the upper portion of the attachment hole 35 are not necessarily arranged in the manner of having fourfold symmetry or twofold symmetry (i.e. 90°-rotational symmetry or 180°-rotational symmetry) in relation to the axis 33 as long as one of the side surfaces of the upper portion has the curved-surface section 35b in a convex shape. In addition, the curved-surface sections 35b may be a part of the curved surface that forms the surface of a three-dimensional object of a doughnut shape or a part of a similar curved surface. Furthermore, it is preferable that the side surfaces comprised of the planar-surface sections 35a in the lower portion of the attachment hole 35 have a taper attached thereto, the taper having dimensions that become smaller toward the bottom surface. The side surfaces comprised of the planar-surface sections 35a may also be processed by embossing or the like to have concave and convex portions such that the plane going through the top parts of the convex portions would be flat.

The rectangular bottom surface of the attachment hole 35 has a side, for example, of 120 μm. The curvature radius of each of the convex curved-surface sections 35b is approximately 500 μm. The lower portion of the attachment hole 35 may have a different form conforming to the size or the shape of the profile of the optical transmission medium to be inserted. In addition, the upper portion of the sealing resin 31, which forms the attachment hole 35, can have the curvature that corresponds to the bend radius of the optical transmission medium to be inserted.

The bottom face of the sealing resin 31 is positioned so as not to protrude from the bottom face of the external terminals 13. In this way, the bottom face of each of the external terminals 13, to be used as the connecting terminal, can be exposed so as to be connectable to a mounting board (not-illustrated). The external terminals to be used can have a shape other than that of the external terminals 13 mentioned above, as long as the external terminals form a surface mount device (SMD). For example, the external terminals may have a shape in which the external terminals each protrude from the corresponding side faces of the sealing resin 31 and then are bent into a gullwing shape. Instead, the external terminals may form a flat shape by being exposed at the bottom face or the side faces of the bottom part of the sealing resin 31. Alternatively, a shape that includes some of the characteristics of both of the above-mentioned shapes may also be possible.

Next, a description will be given of a method of manufacturing the optical semiconductor device 5. A planar lead frame is formed by press punching or the like to have the shapes that are to be the internal leads 11 and the external terminals 13. Then, the optical semiconductor element 21 is fixed and bonded to a certain position of the planar lead frame by using the Au wire 27. An alignment hole in the lead frame is accurately positioned against a mold that has a protrusion (a pin) formed at a certain position thereof, the protrusion used to form the attachment hole 35. A mold resin, which is to be the sealing resin 31, is injected into the mold, and the mold resin then becomes solidified. In this way, it is possible to obtain the sealing resin 31 that has the attachment hole 35 exactly facing the functional region 23 of the optical semiconductor element 21. Subsequently, the optical semiconductor device 5 is completed through the processes of plating, cutting, bending and the like. In order to enhance the accuracy in positioning the optical semiconductor element 21, the lower surface of the lead frame at a time of being punched can be used as the surface for mounting the optical semiconductor element 21.

Next, a description will be given of an optical transmission device formed by mounting an optical transmission medium on of the optical semiconductor device 5. As shown in FIG. 2, an optical transmission device 1 has a configuration in which an optical semiconductor medium 41 is fixed to the attachment hole 35 of the optical semiconductor device 5 by use of an adhesive material 45 in the following position. Specifically, one end of the optical semiconductor medium 41 is pressed into and thus attached to the attachment hole 35 of the optical semiconductor device 5. The optical semiconductor medium 41 is bent along one of the side faces and the top face of the sealing resin 31 that defines the attachment hole 35.

The optical transmission medium 41 is formed of a core 42 and a clad 43 that covers the circumference of the core 42. The core 42 is made of an epoxy resin having a relatively high refractive index, and the clad 43 is made of an epoxy resin having a relatively low refractive index. The cross section of the core 42 is in an approximately square shape having a side, for example, of 60 to 80 μm. The clad 43 covers the circumference of.the core 42 while keeping the film thickness substantially uniform, and having an external shape of a square having a side approximately 120 μm. In the case where a taper, the dimensions of which become smaller toward the bottom surface, is attached to the attachment hole 35, the clad 43 also includes a taper that corresponds to that of the attachment hole 35. The optical transmission medium 41 is divided into three portions: a first portion, which is attached to the lower part of the attachment hole 35; a second portion, which is contiguous to the first portion; and a third portion, which is contiguous to the second portion. The first portion and the third portion are each formed into a straight line, and are in a relation of forming a right angle. The second portion is bent along the curvature of the attachment hole 35.

The bending shape of the optical transmission medium 41 may be shaped in advance, or may be shaped, in attaching the optical transmission medium 41, by bending the line-shaped optical transmission medium 41 along a surface of the attachment hole 35. The optical transmission medium 41 may be provided as a part of a film optical waveguide, or may be formed as an optical fiber. In the lower part of the attachment hole 35, the surfaces of the sealing resin 31 are in contact with the outer surfaces of the optical transmission medium 41 without having substantially any gap therebetween. The cross section of the optical transmission medium 41 may have a shape other than the square shape. Furthermore, the size, the material and the like of each of the core 42 and the clad 43 can be changed so as to be better suited for requirements for optical transmission.

The adhesive material 45 is, for example, an epoxy resin adhesive material, and fixes the optical transmission medium 41 to the sealing resin 31 as follows. The adhesive material 45 covers or buries the top face of the sealing resin 31, the optical transmission medium 41, which is mounted on the top face of the sealing resin 31, the attachment hole 35, and the like. The adhesive material 45 may be transparent to outgoing or incident light. Alternatively, the adhesive material 45 may be opaque except a portion at the lower part of the attachment hole 35, the portion being in contact with the end part of the optical transmission medium 41.

As mentioned above, the optical semiconductor device 5 includes: the optical semiconductor element 21; the internal leads 11, to which the optical semiconductor element 21 is firmly fixed; the transparent sealing resin 31, which is provided with the attachment hole 35 for an optical transmission device, and which seals the optical semiconductor element 21 and the internal leads 11; and the external terminals 13 adapted for surface mount. With this configuration, the optical semiconductor device 5 can be connected to a surface of a mounting board (not shown) by use of a joining material, such as solder. Accordingly, it is possible to mount the optical semiconductor device 5 without requiring a mounting board that includes a hub corresponding to an insertion-type lead, which makes it possible to prevent an area required for mounting the optical semiconductor device 5 (hereinafter, this area will be simply called a “device mounting area”) from extending to the mounting board.

In addition, the optical transmission device 1 has a configuration in which the optical transmission medium 41 is fixed to the attachment hole 35 of the above-described optical semiconductor device 5 by use of the adhesive material 45. One end of the optical transmission medium 41 is attached to the attachment hole 35, and the optical transmission medium 41 is bent toward the other end along one of the side faces of the sealing resin 31, which form the attachment hole 35, and the top face of the sealing resin 31 contiguous to the side face. With this configuration, the emitted light or the received light is refracted at approximately 900 in the optical transmission device 1. As a result, the device mounting area above an optical transmission device can be minimized as compared to the conventional case in which an optical transmission medium is bent outside the upper part of an optical transmission device to reach another optical transmission device disposed on another end of a mounting board. Moreover, the optical transmission device 1 also produces the same effect that enables surface mount as that of the optical semiconductor device 5.

Furthermore, the attachment hole 35 that accurately faces the functional region 23 of the optical semiconductor element 21 is obtained by use of the mold, and thereafter the optical transmission medium 41 is pressed into and fixed to the attachment hole 35. This makes it possible to obtain an accurate relationship between the functional region 23 of the optical semiconductor element 21 and the optical transmission medium 41.

In addition, the optical transmission device 1 can be completed by joining the optical semiconductor device 5 to the surface of the mounting board with a joining material, such as solder, and then by attaching the optical transmission medium 41 to the optical semiconductor device 5 on the mounting board. In this way, it is possible to more flexibly provide an optical connection to the optical transmission device 1.

### Second Embodiment

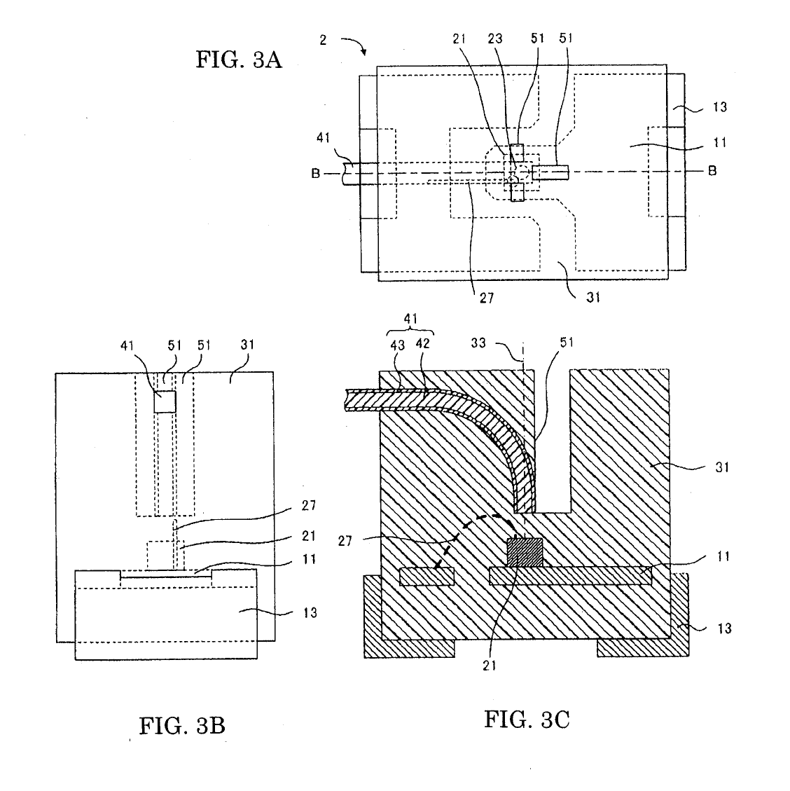

An optical transmission device according to a second embodiment of the present invention will be described with reference to FIGS. 3A to 3C. FIGS. 3A to 3C schematically show a configuration of the optical transmission device. FIG. 3A is a plane view, FIG. 3B is a side view, and FIG. 3C is a sectional view taken along the line B-B in FIG. 3A. The optical transmission device of this embodiment is different from that of the first embodiment in that an optical transmission medium is buried in a sealing resin. Descriptions will be given below only of the components different from those of the first embodiment, while the descriptions for the same components as those of the first embodiment are omitted with the same reference numerals and symbols given thereto.

As shown in FIGS. 3A to 3C, an optical transmission device 2 includes an optical semiconductor element 21, internal leads 11, a translucent sealing resin 31, an optical transmission medium 41, external terminals 13 and the like, as similar to the optical transmission device 1 of the first embodiment. In contrast with the optical transmission device 1, in the optical transmission 2 of this embodiment, the optical transmission medium 41 is buried in the sealing resin 31 and then fixed thereto. Accordingly, one end face of the optical transmission medium 41 accurately faces the functional region 23 of the optical semiconductor element 21. Furthermore, three guide holes 51 are provided next to the one end face of the optical transmission medium 41, and each of the guide holes 51 has a rectangular cylinder shape perpendicular to the top face of the optical semiconductor element 21.

Next, a description will be given of a method of manufacturing the optical transmission device 2 with any references to drawings. The manufacturing method of the optical transmission device 2 is similar to that of the optical semiconductor device 5 of the first embodiment up to the process of fixing and bonding the optical semiconductor element 21 to a certain position on a planar lead frame with an Au wire 27.

Three protrusions (guide pins), each of which is in a rectangular-cylinder shape, are provided to certain positions on a mold and are used to form the respective guide holes 51. The optical transmission medium 41 is formed in advance into a shape having two linear portions, which are contiguous to a bent portion of the optical transmission medium 41, and which are approximately at right angles to each other. One of the linear portions is formed to have a predetermined length. The linear portion of the optical transmission medium 41 that is formed to have the predetermined length is fixed with the three guide pins, and then an alignment hole of the lead frame is accurately positioned against the mold. Thereafter, a mold resin to be the sealing resin 31 is injected into the mold. After the mold resin is solidified, the three guide pins are pulled out together with the mold. As a result, the sealing resin 31 that fixes the optical transmission medium 41 accurately facing the functional region 23 of the optical semiconductor element 21 can be formed.

Subsequently, through processes similar to those in the method of manufacturing the optical semiconductor device 5 according to the first embodiment, the optical transmission device 2 having the guide holes 51 is completed. The number of the guide pins does not necessarily need to be three, nor does the shape of each of the guide pins need to be a rectangular cylinder, as long as the guide pins are capable of fixing the optical transmission medium 41 during the molding process. In addition, to make it easier to pull out the guide pins, each of the guide pins may be formed in a shape of being relatively narrow at the end portion, in other words, each of the guide holes 51 may be formed to have dimensions that become larger toward the top face of the sealing resin 31.

As described above, in the optical transmission device 2, the optical transmission medium 41 is fixed in the sealing resin 31, the optical transmission medium 41 including the two linear portions, each of which is contiguous to the bent portion, and which are at right angles to each other. In the optical transmission medium 41, one end of one of the linear portions faces the functional region 23 of the optical semiconductor element 21 while the other linear portion contiguous in the direction of the other end is extended from one of the side faces of the sealing resin 31 to the outside of the sealing resin 31. As is the case with the optical transmission device 1 of the first embodiment, the mounting the optical transmission device 2 of this embodiment on the mounting board (not shown) makes it possible to minimize the device mounting area above the optical transmission device.

In addition, since the optical transmission medium 41 is fixed to the optical transmission device 2 during the molding process, processes for manufacturing the optical transmission device 2 can be reduced compared to those for manufacturing the optical transmission device 1 of the first embodiment. Moreover, the length of the linear portion of the optical transmission medium 41 can be made shorter in the optical transmission device 2 than in the optical transmission device 1, the linear portion facing the functional region 23 of the optical semiconductor element 21 and being contiguous to the bent portion of the optical transmission medium 41. Consequently, the height of the optical transmission device 2 can be made lower than that of the optical transmission device 1.

In consideration of mounting optical transmission devices on a mounting board, it is desirable to employ, for one end side of the mounting board, the optical transmission device 2 that suits usage conditions, and to employ, for the other end side, the optical transmission device 1 of the first embodiment. In this way, the time required for mounting can be reduced compared to the case where two optical transmission devices 1 of the first embodiment are employed to be mounted on both ends of the mounting board. It is also possible to employ the optical transmission devices 2 to both ends of the mounting board when the length, the direction and the like, of the optical transmission medium 41 are clearly defined. With this configuration, the time required for mounting can be further reduced.

The present invention is not limited to the above-mentioned embodiments, and various changes may be made therein without departing from the spirit of the present invention.

For example, in the above embodiments, examples in which the optical semiconductor element is mounted on the optical semiconductor device or the optical transmission device are described. However, in addition to the optical semiconductor element, a reception integrated circuit (IC), a transmission IC or the like can be mounted on the internal leads of the optical semiconductor device or the optical transmission device. In this case, an external terminal adapted for surface mount needs to be formed additionally for the reception IC, the transmission IC or the like.

As described above, present embodiments can provide an optical semiconductor device and an optical transmission device that each make it possible to minimize an area required for mounting the device.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An optical semiconductor device comprising:
an internal lead;
an optical semiconductor element mounted on the internal lead and electrically connected to the internal lead;
a sealing resin for sealing the optical semiconductor element and the internal lead, the sealing resign provided with an attachment hole formed by side surfaces and a bottom surface, the side surfaces each including a convex curved-surface section in an upper portion and a planar-surface section in a lower portion contiguous to the curved-surface section, and the bottom surface being in a lower portion and facing the front surface of a functional region for emitting or receiving light of the optical semiconductor element, and the sealing resin being transparent to outgoing or incoming light; and
an external terminal connected to the internal lead and adapted for surface mount.

2. The optical semiconductor device according to claim 1, wherein the planar-surface sections in the lower portion of the attachment hole is provided with a taper the dimensions of which become smaller toward the bottom surface.

3. The semiconductor device according to claim 1, wherein the planar-surface sections in the lower portion of the attachment hole is perpendicular to the front surface of the functional region of the optical semiconductor element.

4. The semiconductor device according to claim 1, wherein the sealing resin has an upper surface being contiguous to the curved-surface section and the upper surface of the sealing resin is parallel to the front surface of the functional region of the optical semiconductor element.

5. The semiconductor device according to claim 1, wherein the axis that perpendicularly passes through the front surface of the functional region of the optical semiconductor element corresponds to the axis that passes through the center of the attachment hole.

6. The semiconductor device according to claim 1, wherein the surface of the planar-surface sections in the lower portion of the attachment hole is processed by embossing to have concave and convex portions such that the plane going through the top parts of the convex portions is flat.

7. The semiconductor device according to claim 1, wherein a hole is provided next to the attachment hole of the sealing resin.

8. An optical transmission device comprising:
an internal lead;
an optical semiconductor element mounted on the internal lead and electrically connected to the internal lead;
a sealing resin for sealing the optical semiconductor element and the internal lead, the sealing resin being transparent to outgoing or incoming light;
an optical transmission medium having one end face disposed so as to face the front surface of a functional region for emitting or receiving light of the optical semiconductor device, and having a parallel portion and a linear portion fixed in contact with the sealing resin, the parallel portion being contiguous to the one end face and being parallel to the axis perpendicularly passing through the center of the front surface, and the linear portion being contiguous to the parallel portion and forming a certain angle with the parallel portion; and
an external terminal connected to the internal lead and adapted for surface mount.

9. The optical transmission device according to claim 8, wherein the certain angle is approximately 90°.

10. The optical transmission device according to claim 8, wherein the optical transmission medium is fixed inside the sealing resin.

11. The optical transmission device according to claim 8, wherein the optical transmission medium is fixed to the sealing resin by use of an adhesive material.

12. The optical transmission device according to claim 8, wherein the sealing resin has an attachment hole and the optical transmission medium pass through the attachment hole.

13. The optical transmission device according to claim 12, wherein the attachment hole is provided with a taper the dimensions of which become smaller toward the bottom of the attachment hole.

14. The optical transmission device according to claim 12, wherein the attachment hole has a portion whose surface is perpendicular to the front surface of the functional region of the optical semiconductor element.

15. The optical transmission device according to claim 12, wherein the axis that perpendicularly passes through the front surface of the functional region of the optical semiconductor element corresponds to the axis that passes through the center of the attachment hole.

16. The optical transmission device according to claim 12, wherein the attachment hole has a portion which is processed by embossing to have concave and convex portions such that the plane going through the top parts of the convex portions is flat.

17. The optical transmission device according to claim 8, wherein the sealing resin has an upper surface parallel to the front surface of the functional region of the optical semiconductor element.

18. The optical transmission device according to claim 8, wherein a hole is provided next to the portion of the optical transmission medium parallel to the axis, the hole having an opening on the side of the sealing resin opposite to a face for the surface mount.
